(19) United States
(12) Patent Application Publication
(10) Pub. No.: US 2011/0014573 A1
(43) Pub. Date: Jan. 20, 2011

(54) SYSTEM FOR ENGRAVING FLEXOGRAPHIC PLATES

(76) Inventors: Eynat Matzner, Adi (IL); David Aviel, Tel Mond (IL); Ophira Melamed, Shoham (IL)

Correspondence Address: EASTMAN KODAK COMPANY;PATENT LEGAL STAFF, 343 STATE STREET, ROCHESTER, NY, 14650-2201, US

(21) Appl. No.: 12/502,267

(22) Filed: Jul. 14, 2009

(51) Int. Cl. G03F 7/20; G03B 27/42

(52) U.S. Cl. 430/306; 355/53

(57) ABSTRACT

A system for engraving flexographic printing plates includes a flexographic printing plate comprised of at least two ablation layers, a printing ablation layer and a non-printing ablation layer. In addition the system includes a laser source adapted to ablate the flexographic plate. The laser source is comprised of a first group of one or more radiation sources each emitting radiation on the printing ablation layer, and a second group of one or more radiation sources each emitting radiation on the non-printing ablation layer.

### CROSS REFERENCE TO RELATED APPLICATIONS

Reference is made to commonly-assigned U.S. patent application Ser. No. 11/615,025 (U.S. Patent Publication No. 2008/0153038), filed Dec. 22, 2006, entitled HYBRID OPTICAL HEAD FOR DIRECT ENGRAVING OF FLEXOGRAPHIC PRINTING PLATES, by Siman-Tov et al., the disclosure of which is incorporated herein.

### FIELD OF THE INVENTION

This invention relates to an optical imaging head, a printing plate construction, and methods for direct engraving of flexographic printing plates.

### BACKGROUND OF THE INVENTION

Flexography is a method of printing whereby a flexible plate with a relief image is wrapped around a cylinder, the relief image is inked, and the ink is then transferred to a suitable printable medium. The process is used in the packaging industry wherein the plates must be sufficiently flexible and the contact sufficiently gentle to print on uneven substrates such as corrugated cardboard as well as flexible materials such as polypropylene film. The quality of the printing in this manner is inferior to processes such as lithography and gravure, but nevertheless it is useful in certain markets. In order to accommodate the various types of printing media, the flexographic plates should have a rubbery or elastomeric nature whose precise properties can be adjusted for each particular printable medium.

In addition, when the flexographic printing plates are formed and/or imaged in a flat form, they should be flexible for bending around a cylinder for rotary printing. This can present more of a problem than with offset lithographic plates because the thickness of flexographic printing plates is generally several millimeters instead of fractions of a millimeter. Materials that are flexible, such as one or two μm films, can be rigid and inflexible at one or more mm.

It has long been recognized that the simplest way of making a flexographic printing plate would be by direct engraving using laser beam ablation, thereby eliminating the need for complex post plate image processing such as multiple types of exposures, washing with solvents and long drying of the plate.

Despite the limitations of carbon dioxide lasers, they are now being used commercially in flexographic engraving machines. They are known for slow and expensive imaging with limited resolution. However, the advantages of direct engraving are sufficient to ensure their commercial use in instances where fast imaging and high print quality are not required. It would be preferable to use infrared diodes that produce radiation in the near infrared and infrared (approximately 700 to 1200 nm) and have the advantages of high resolution and relatively low laser cost so that they can be used in large arrays. Until now, although the use of such lasers is described in many publications, they are not In industrial use because even when combined with the most sensitive imageable elements available, satisfactory engraving has not been achieved.

Engraving with an infrared diode laser (or ablative imaging) differs from engraving with a carbon dioxide laser in that a compound absorbing suitable radiation (that is, IR radiation) is usually incorporated into the imaged coating. The recent availability of high power (for example, 8 watts) IR-laser diodes opens up opportunity for the use of relatively low cost laser diode arrays capable of engraving flexographic blanks as described in WO 2005/84959 (Figov).

Relief depth in the resulting image is an issue with laser engraving because the deeper the required relief, either more power is required or it takes longer to engrave or image the plate, for a specific material. Use of material which ablates more easily is another approach adapted to achieve a deeper relief in the same engraving time. Direct engraving of a flexography plate requires carving three-dimensional (3-D) areas, on plate material, with a laser system. This is remarkably different from two-dimensional (2-D) imaging techniques that require post processing steps to produce the 3-D features.

The requirements, mentioned above, introduce several challenges for the laser imaging system and the related media:
1. The laser system must have sufficient power to ablate the material at an acceptable throughput.
2. The laser spot should be small enough, and the material suitable to achieve the fine detail ablation, as required for quality printing. Although high power density does not necessary conflict with laser focusability, from a practical perspective, these lasers offer significantly higher cost per watt of output optical power than broad spot lasers. As a result, it is desirable to operate with broad laser sources, that produce high output optical power, rather than with small spot sources, that may have high power density but relatively low total power output. It is therefore appealing to use a laser system that combines the characteristics of a fine spot laser source to process areas which require fine detail screening and a broad spot laser source for portions of the image where features comprise large solid areas.
3. In addition, it is desirable to use a flexographic plate with more than one imaging layer, whereby each of the different layers is optimized for best imaging performance, in conjunction with different laser sources, such as fine spot and broad spot laser sources.

The layers in the plate should be optimized in such a way that both printing performance and imaging performance are optimized so that printing layers are most suitable for high resolution imaging by one laser source and for printing high resolution dot, low dot gain and excellent ink transfer. The other imaging layers, which will not be used for printing, are optimized for fast imaging with a second laser source to achieve high throughput, without comprising good printing characteristics. U.S. Pat. No. 7,419,766 (Kimelblat et al.) shows an example of a multi-layer flexographic plate wherein the top layer is an ablatable layer designed to be ablated by a laser source, and the second layer is not ablatable.

### SUMMARY OF THE INVENTION

Briefly, according to one aspect of the present invention a system for engraving flexographic printing plates includes a flexographic printing plate comprising from at least two ablation layers, a first ablation layer and a second ablation layer wherein the first ablation layer is a printing layer and the second ablation layer is a non-printing layer; a first group of one or more radiation sources each emitting radiation having substantially the same intensity; a first set of one or more optical elements coupled to the first group of one or more radiation sources for imaging radiation emitted from the first group of one or more radiation sources on the first ablation layer; a second group of one or more radiation sources each emitting radiation having substantially the same intensity; a second set of one or more optical elements coupled to the second group of one or more radiation sources for imaging radiation emitted from the second group of one or more radiation sources on the second ablation layer; wherein the intensity and spot size of said first group of one or more radiation sources is different from the intensity and spot size of the second group of one or more radiation sources; and wherein the first and second groups of radiation sources operate simultaneously.

The invention and its objects and advantages will become more apparent in the detailed description of the preferred embodiment presented below.

### BRIEF DESCRIPTION OF THE DRAWINGS

FIG. 1 is a diagram of a hybrid optical head concept arranged on two separate optical carriages according to the present invention;

FIG. 2 shows a prior art cross-sectional view of a flexographic printing plate precursor with a single ablation layer;

FIG. 3 shows a cross-sectional view of an imaged layer the flexographic printing plate shown in FIG. 2;

FIG. 4 shows a cross-sectional view of a flexographic printing plate according to the present invention with more than one ablation layer;

FIG. 5 shows a cross-sectional view of an imaged layer of the flexographic printing plate shown in FIG. 3; and

FIG. 6 shows imaging laser sources (fine and broad) each imaging on a different layer of the flexographic plate (shown in FIG. 3).

### DETAILED DESCRIPTION OF THE INVENTION

The combination of radiation sources with high power broad spots and low power fine spots, referred to as a hybrid optical head system (HOHS), is well suited for 3-D processing of direct engraving flexography applications. The HOHS is described in detail in the U.S. Patent Publication No. 2008/0153038 (Siman-Tov et al.).

The HOHS may be configured with at least two groups of radiation sources, the groups comprising at least one radiation source, wherein the radiation sources within the groups emit radiation having the same intensity and spot size, different from the intensity and spot size of radiation sources in other groups. The groups of radiation sources operate simultaneously. Radiation sources include, but are not limited to, lasers, laser diodes, multi-emitter laser diodes laser bars, laser stacks, fiber lasers, and the like. For example, a lower power fine laser source may assist in processing solid areas; however, a high power broad laser source may only operate in areas that are greater than or equal to its spot size. The laser sources, fine and broad, may be integrated into a single optical head, or separated into their own separate mounted heads. In each configuration, the laser sources are controlled and driven independently of each other.

A fine laser source, or a multiplicity of fine laser sources, may comprise diode lasers having a single emitter, such as, for example, both fine and broad source lasers are available in a fiber-coupled and non-fiber-coupled configurations. In the fiber-coupled configuration, the laser is coupled to a fiber using a separate focusing lens or a lens defined by processing the fiber end to a surface capable of refracting the light into the fiber. The size of the aperture emerging from the fiber is determined by the radial dimension of the fiber. The light that is output from the aperture diverges and needs to be imaged by using a lens, or system of lenses, to result in the desired spot size.

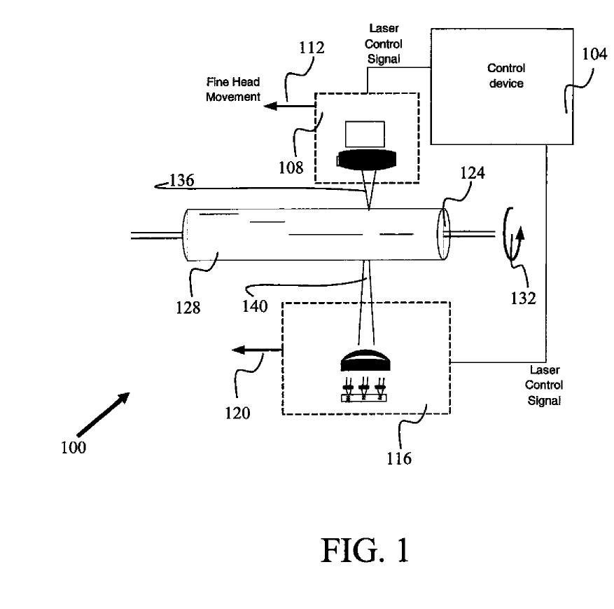

FIG. 1 illustrates one embodiment of a HOHS 100 where fine laser source 108 and broad laser source 116 are mounted on carriages 112 and 120, respectively, which move along the longitudinal axis of a rotating drum 124 on which flexographic plate 128 is mounted, drum 124 rotates in rotation direction 132. Laser sources 108 and 116 are controlled by control device 104 and carriages 112 and 120 may be placed independently of each other, at different locations with respect to the rotating drum 124. The fine laser source 108 emits laser beam 136 on plate 128, and the broad laser source emits beam 140 on plate 128.

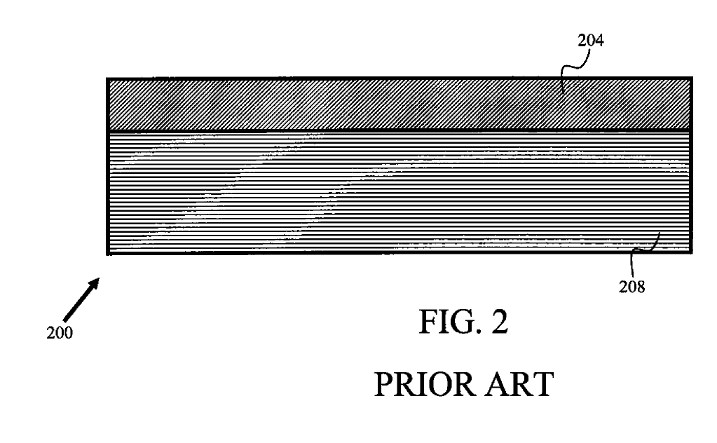

FIG. 2 shows a cross section of a flexographic plate 200. Flexographic plate 200 comprises, in general terms, a single ablative layer 204, and additional non-ablative layers, such as support layer 208. Flexographic plate such as plate 200 is described in the commonly-assigned U.S. Pat. No. 7,419,766 (Kimelblat et al.).

In operation, a flexographic plate 200 is attached to rotating drum 124 and then spun. While spinning, control device 104 directs broad laser source 116 to ablate certain large areas on imaging layer 204 that are greater than or equal to the spot size of the broad laser source 116; while fine laser source 108 is directed to ablate certain small areas on imaging layer 204, areas requiring fine detail and large areas where fine laser source 108 is directed to operate. Laser sources 108 and 116 are moved on their respective carriages 112 and 120, so as to locate the laser sources 108 and 116 in the area where they need to operate.

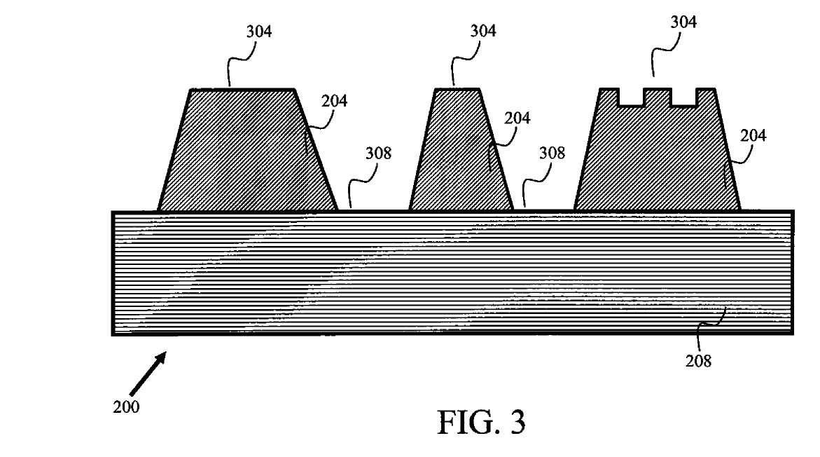

The imaging process described above is not new, it can be accomplished by deploying an imaging head presented in the U.S. Patent Publication No. 2008/0153038, imaging a flexographic plate 200 (described in U.S. Pat. No. 7,419,766). FIG. 3 shows a flexographic plate 200 after being imaged. The support layer 208 was not affected. Imaging layer 204 was ablated in several areas. The ablation process resulted in imageable areas 304 at the upper parts of layer 204, and non-imageable areas 308 (fully ablated) at the bottom part of imaging layer 204. During printing process, the upper imageable areas 304 of flexographic plate 200 will press on the ink blanket, causing ink transfer to the substrate, in imageable areas 304. The bottom non-imageable areas 308 will not reach the ink blanket; therefore ink will not be transferred to the substrate from non-imageable areas 308.

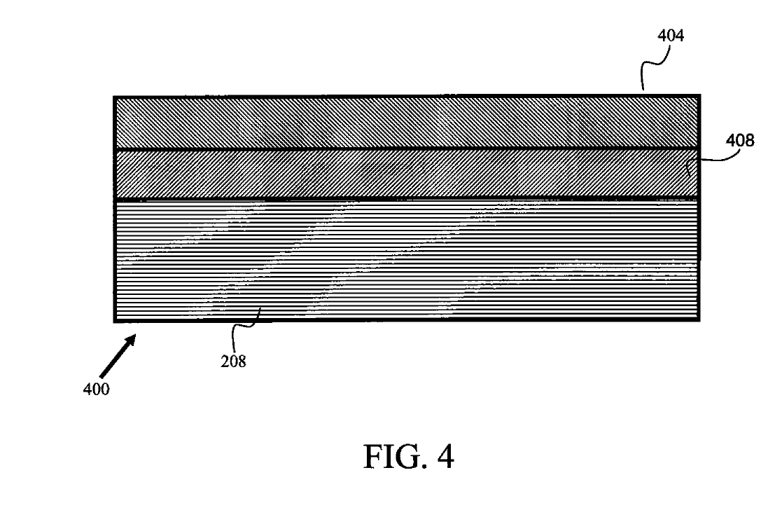

FIG. 4 shows a cross section of a flexographic plate 400 with multiple image able layers. Flexographic plate 400 in general terms includes a support layer 208 and at least two ablative layers 408 and 404. The upper ablative layer 404 is used to engrave imaged data to be printed. Printing layer 404 is essentially the printing layer. The lower ablated layer 408 represents the non printable areas, areas that will not show during the printing process. Flexographic plate 400 is designed to operate in the most efficient manner with HOHS 100 features.

Printing layer 404 is constructed from a combination of materials such as thermosetting acrylates, polyurethanes, vulcanized rubbers, synthetic rubbers and other thermosetting elastomers. Those materials, by their design or in addition include in the matrix materials such as fillers, making printing layer 404, imageable by infra red (IR) based laser and possessing certain mechanical and chemical properties, and therefore is most suitable for high quality printing. Some of the main characteristics of such printing layer 404 are: good mechanical properties; good resistance to heat, mechanical and chemical attack; good affinity to different inks; and ability to be imaged by laser sources to produce high resolution dots, and being able to hold small dots. Due to these characteristics, printing layer 404 is well suited to serve as a printing layer. Non-printing layer 408 is constructed from materials such as thermosetting acrylates, polyurethane, vulcanized rubbers, synthetic rubbers, and other thermosetting elastomers. Those materials, by their design or in addition include in the matrix materials such as exothermic oxidizing groups and fillers with high tendency to decompose with heat and ablate, or having low density or entrapped air within them, or having weak bonds which can ablate easily. Non-printing layer 408 may be softer and less durable than printing layer 404, and therefore will easily ablate, exhibiting high imaging throughput.

Fine laser source 108 is designed to image printing layer 404 and broad laser source 116 is designed to ablate the non-printable layer 408. The typical thickness of printing layer 404 is in the range of 30-350 microns and of non-printing layer 408 is in the range of 100-1000 microns.

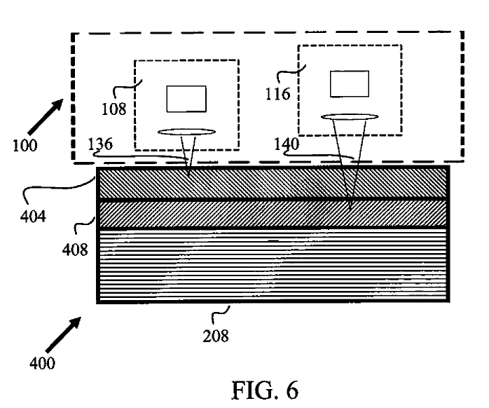

In operation as is depicted in FIGS. 1 and 6, a flexographic plate 400 is attached to rotating drum 124 and then spun. While spinning, control device 104 directs broad laser source 116 to ablate certain large areas on imaging non-printing layer 408 that are greater than or equal to the spot size of the broad laser source 116; while fine laser source 108 is directed to ablate certain small areas on imaging printing layer 404, areas requiring fine detail and large areas where fine laser source 108 is directed to operate. Laser sources 108 and 116 are moved on their respective carriages 112 and 120, so as to locate the laser sources 108 and 116 in the area where they need to operate.

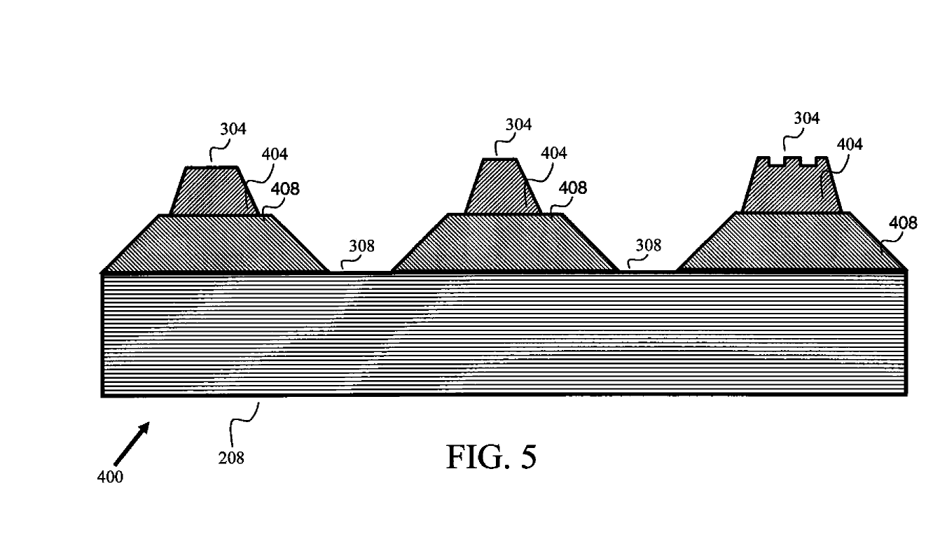

FIG. 5 shows flexographic plate 400, after being imaged by HOHS 100. The printing layer 404 is ablated by fine laser source 108 creating printable imageable areas 304. The lower layer (non-printable) 408, due to its softer features than printing layer 404, is ablated by the broad laser source 116 to create wider chunks than those created in printing layer 404. The larger chunks engraved in non-printing layer 408 will serve as support bases to the engraved areas from printing layer 404.

The invention has been described in detail with particular reference to certain preferred embodiments thereof, but it will be understood that variations and modifications can be effected within the scope of the invention.

### PARTS LIST

100 hybrid optical head system (HOHS)
104 control device
108 fine laser source
112 fine laser source carriage
116 broad laser source
120 broad laser source carriage
124 rotating drum
128 flexographic plate on drum
132 drum 124 rotation direction
136 fine laser source beam (focused on upper imaging layer)
140 broad laser source beam (focused on bottom imaging layer)
200 flexographic plate
204 imaging (ablative) layer
208 support layer
304 imageable area (ink transfer area)
308 non-imageable area (no ink transfer area)
400 flexographic plate with multiple imageable layers
404 ablation area—printing layer
408 ablation enhanced layer—non printing-layer

1. A system for engraving flexographic printing plates, comprising:
a flexographic printing plate comprising from at least two ablation layers, a first ablation layer and a second ablation layer wherein said first ablation layer is a printing layer and said second ablation layer is a non printing layer;
a first group of one or more radiation sources each emitting radiation having substantially the same intensity;
a first set of one or more optical elements coupled to the first group of one or more radiation sources for imaging radiation emitted from the first group of one or more radiation sources on said first ablation layer;
a second group of one or more radiation sources each emitting radiation having substantially the same intensity;
a second set of one or more optical elements coupled to the second group of one or more radiation sources for imaging radiation emitted from the second group of one or more radiation sources on said second ablation layer;
wherein the intensity and spot size of said first group of one or more radiation sources is different from the intensity and spot size of said second group of one or more radiation sources; and
wherein said first and said second groups of radiation sources operate simultaneously.

2. The system of claim 1 wherein said radiation sources of said first group are selected from a group consisting at least of laser diodes, multi emitter laser diodes, laser bars, laser stacks, fiber lasers, or a combination thereof.

3. The system of claim 1 wherein said radiation sources of said second group are selected from a group consisting at least of laser diodes, multi emitter laser diodes, laser bars, laser stacks, fiber lasers, or a combination thereof.

4. The system of claim 1 wherein the first group of one or more radiation sources is capable of engraving fine details on said first ablation layer of said flexographic printing plate.

5. The system of claim 1 wherein the second group of one or more radiation sources is capable of engraving broad details on said second ablation layer of said flexographic printing plate.

6. The system of claim 1 wherein said first ablation layer comprises:
at least one cross linked polymeric binder;
IR absorber such as pigment or dye wherein said IR absorber is adapted to convert light to heat; and
fillers for enhancing the durability of said layer.

7. The system of claim 1 wherein said second ablation layer comprises:
at least one cross linked polymeric binder;
IR absorber such as pigment or dye wherein said IR absorber is adapted to convert light to heat;
fillers for enhancing the durability of said layer; and
material adapted to enhance ablation rate.

8. The system in claim 1 wherein the first ablation layer is a combination of a plurality of coated layers, wherein each of said coated layers have the same composition.

9. The system in claim 1 wherein the second ablation layer is a combination of a plurality of coated layers, wherein each of said coated layers have the same composition.

10. The system of claim 6 wherein said binder is a cross linked polyurethane.

11. The system of claim 7 wherein said binder is a cross linked polyurethane.

12. The system of claim 6 wherein said IR absorber is carbon black.

13. The system of claim 7 wherein said IR absorber is carbon black.

14. The system of claim 6 wherein said fillers are selected from a group consisting of at least of silica, calcium carbonate, magnesium oxide, talc, mica, or a combination thereof.

15. The system of claim 7 wherein said fillers are selected from a group consisting of at least of silica, calcium carbonate, magnesium oxide, talc, mica, or a combination thereof.

16. The system in claim 10 wherein nitro cellulose groups are connected to said polyurethane elastomer.

17. The system in claim 7 wherein hollow spheres with a diameter smaller than 50 microns are mixed to said layer to enhance the ablation.

18. The system of claim 1 wherein the ratio between the ablation of said first ablation layer and the ablation rate of said second ablation layer is higher than 1.1.

19. The system of claim 1 wherein said first ablation layer is selected from the group consisting at least of thermosetting acrylates, polyurethanes, vulcanized rubbers, synthetic rubbers, thermosetting elastomers, or a combination thereof.

20. The system of claim 1 wherein said second ablation layer is selected from the group consisting at least of thermosetting acrylates, polyurethane, vulcanized rubbers, synthetic rubbers, thermosetting elastomers, or a combination thereof.

21. The system of claim 1 wherein the thickness of said first ablation layer is in the range from 30 microns to 350 microns.

22. The system of claim 1 wherein the thickness of said second ablation layer is in the range from 100 microns to 1000 microns.

23. A method for engraving flexographic printing plates, comprising:
providing a flexographic printing plate comprising at least a first ablation layer and a second ablation layer, wherein said first ablation layer is a printing layer and said second ablation layer is a non printing layer;
emitting radiation having substantially the same intensity from a first group of one or more radiation sources;
imaging radiation emitted from the first group of radiation sources on said first ablation layer of said flexographic printing plate;
emitting radiation having substantially the same intensity from a second group of one or more radiation sources;
imaging the radiation emitted from the second group of radiation sources on said second ablation layer of said flexographic printing plate;
wherein an intensity and spot size of said first group of one or more radiation sources is different from an intensity and spot size of said second group of one or more radiation sources; and
wherein said first and said second groups of radiation sources operate simultaneously.

24. The method of claim 23 further comprising engraving fine details on said first ablation layer with the first group of one or more radiation sources.

25. The method of claim 23 further comprising engraving broad details on the said second ablation layer of said flexographic printing plate with the second group of radiation sources.

26. The system of claim 1 wherein said second group of radiation sources removes both said first layer and said second layer.
